(19) United States
(12) Patent Application Publication
(10) Pub. No.: US 2015/0237738 A1
(43) Pub. Date: Aug. 20, 2015

(54) METHOD FOR PRODUCING A CIRCUIT BOARD ELEMENT, AND CIRCUIT BOARD ELEMENT

(71) Applicant: JUMATECH GMBH, Eckenthal (DE)

(72) Inventor: Markus Wölfel, Lauf (DE)

(73) Assignee: JUMATECH GMBH, Eckenthal (DE)

(21) Appl. No.: 14/429,070

(22) PCT Filed: Aug. 30, 2013
(86) PCT No.: PCT/EP2013/067988

§ 371 Date: Mar. 18, 2015

(30) Foreign Application Priority Data
Sep. 20, 2012 (DE) 10 2012 216 926.1

(51) Int. Cl. H05K 3/10; H05K 1/09

(52) U.S. Cl. CPC H05K 3/10; H05K 1/09; H05K 2201/0355; H05K 2201/1028; H05K 2201/10287

(57) ABSTRACT

A method for producing a circuit board element, and a corresponding circuit board element, with which it is possible to suppress the risk of delamination in the region of a component (e.g. a wire or a plate-like shaped part) that is embedded in the circuit board element. To this end, the present invention suggests that the surface of the component should be roughened, at least partially, in order to ensure a better adhesive bond with the surrounding cover layer (e.g. a prepreg made of an insulating material compound). The component surface can be roughened by chemical methods such as etching or by purely mechanical methods such as sand blasting.

### CROSS-REFERENCE TO RELATED APPLICATIONS

This application is a National Stage of International Application No. PCT/EP2013/067988 filed Aug. 30, 2013 and also published as WO 2014/044515 on Mar. 27, 2014. The International Application claims priority to German Application No. 10 2012 216 926.1 filed Sep. 20, 2012. All of the above applications are incorporated herein by reference.

### FIELD OF THE INVENTION

The present invention relates to a method of producing a circuit board element, comprising the steps of providing first a component consisting of an electrically conductive material and contacting this component with an electrically conductive foil at at least one contact point, prior to applying then a cover layer to the side of the foil contacting the component.

In addition, the present invention relates to a circuit board element comprising at least one electrically conductive foil, a cover layer which covers the foil on at least one side thereof, and at least one component made of an electrically conductive material, the component being in contact with the foil at at least one contact point and being embedded in the cover layer, at least in certain areas thereof, preferably in full area.

### BACKGROUND

The trend towards increasingly small and, simultaneously, increasingly efficient electronic devices, such a smart phones or tablets, has led to an increase in integration density on circuit boards for years.

In this respect, wire-inscribed circuit boards, in the case of which conducting wires are applied to the upper and/or lower surface of a copper foil, prove to provide distinct advantages. After press-bonding of the foil with an electrically insulating cover layer, normally a prepreg consisting of an epoxy resin glass fiber fabric, the wires are located in the interior of the laminate, embedded in the prepreg.

Making use of this wire-writing technology, which is described e.g. in WO 2008/055672 A1, three-dimensional circuit geometries for extreme packaging densities can be realized in circuit boards. Although many technical restrictions of conventional circuit board technology are overcome in this way, wire-inscribed circuit boards are still improvable as regards their delamination resistance.

Delamination of circuit board elements is a serious challenge, in particular since especially multi-layered circuit boards (multilayers) are subjected to ever-increasing thermal and/or mechanical loads.

Within the last few years, it has been possible to substantially increase the adhesion coefficients between the individual layers of the multilayer, i.e. between the individual copper foils and the respective prepreg layers (layers of epoxy resin glass fiber fabric) disposed therebetween, by treating the surface of the copper foils first with chemical agents (“brown oxide” or “black oxide” treatment) and by using improved epoxy resin mixtures for prepregs.

However, embedding additional components in the prepreg layers of the circuit board leads to an increase in the delamination risk, since delamination occurs first at the “weak points” between the surfaces of the embedded components and the surrounding prepreg, but not at the connection between the treated copper foil surface and the prepreg, said connection having a much higher adhesive strength.

In particular in wire-inscribed circuit boards, the conducting wires embedded in the prepreg lead to a weakening of the adhesive bond.

This problem is still aggravated by the circumstance that the additional wires incorporated in the circuit board interior may be configured as silver-coated copper wires. It is true that the silver layer applied to the copper core by electroplating is not only highly conductive but is, in particular, also excellently weldable. However, in addition to the economic drawbacks (silver-coated copper wires are many times more expensive than wires consisting exclusively of copper), the silver layer, due to its comparatively smooth surface, adheres only very poorly to the surrounding layer of prepreg.

### SUMMARY

It is therefore the object of the present invention to provide a method for producing a circuit board element, and a circuit board element, which allow excellent adhesion between the additional components integrated in the circuit board element and the cover layer surrounding the respective components, so that delamination of the circuit board element in the area of the components embedded in the cover layer is prevented.

Accordingly, this object is achieved by a method for producing a circuit board element, in the case of which the surface of the component is at least partially roughened prior to the application of the cover layer, so that, when the cover layer is applied to the foil, said cover layer is brought into contact with the roughened surface of the component.

Due to the fact that the component embedded in the circuit board element has, instead of a comparatively smooth surface, e.g. instead of a smooth silver metal surface, an at least partially roughened surface, a substantially improved adhesion between the component and the cover layer surrounding the component is ensured. Hence, components can easily be integrated in a multilayer, without delamination of the circuit board being caused as a result of a detachment of the component from the adjoining cover layer. This opens up new fields of use for circuit boards with embedded components (e.g. in the form of wire-inscribed circuit boards). Due to their extreme ambient conditions, these fields of use have appeared to be hardly realizable up to now, e.g. use in the field of high-temperature applications, in automotive electronics by way of example.

According to an embodiment, the roughening of the surface of the component takes place prior to contacting the component with the foil in the case of the method according to the present invention. The roughened component surface has no negative influence whatsoever on the quality of the contact to be established between the component and the foil (e.g. by resistance welding), so that the whole surface of the components can be subjected to a preceding roughening treatment with little effort and a high continuous throughput rate.

In particular, roughening of the surface of the component can be realized by chemical etching, said chemical etching being preferably carried out by immersing the component into a liquid etching the material of the component or by spraying such a liquid onto the component. Prior to the actual microetching process, the components to be treated are cleaned and, in so doing, their metal surfaces are degreased by an acidic or alkaline solution (cleaner). After the microetching process, which may be carried out e.g. in a flooding module with surge nozzles (bond), residues of the etching solution are removed in a cascade-type rinsing module, before the components are finally dried such that no stains remain thereon.

Alternatively, the surface of the component may also be roughened by mechanical processing, e.g. by sand blasting or by spraying on pumice or quartz powder under high pressure, and thus be provided with better adhesion properties. Mechanical roughening processes have the advantage that the surface roughness is produced by mechanical abrasion alone, so that there is no necessity of using aggressive etching solutions, which are expensive to buy and to dispose of.

According to a further embodiment, the application of a cover layer to the side of the foil contacting the component is executed by press-bonding the side of the foil with a prepreg made of an insulating material compound. Said press-bonding is executed such that the copper foil provided with the component and the prepreg (epoxy resin glass fiber fabric blank) are inserted in a laminate press and that, after an application of pressure and heat, the circuit board element is ejected as press-bonded end product, which can be finished by means of well-established processes (etching process from outside and populating with SMD components).

Preferably, a plurality of electrically conductive foils, at least one of which has been contacted with at least one component made of an electrically conductive material, and a plurality of prepregs made of an insulating material compound and inserted between the respective foils are pressed-bonded so as to form a multilayer circuit board element. Especially in the case of such press-bonding for producing a multilayer, sufficient interlaminar adhesion must be ensured between each of the layers, since even individual local lift-offs, which may be caused by components embedded in the prepreg, may result in delamination and, consequently, in a total failure of the multilayer circuit board element.

In addition, the object underlying the present invention is achieved by a circuit board element of the type mentioned at the beginning, in the case of which at least a part of the component surface contacting the cover layer is roughened. Due to the microfine roughening of the component surface, an ideal surface topography for optimum adhesion between the component and the surrounding cover layer is created, so that the risk of delamination of the circuit board element, which originates from the embedded component, can almost be excluded.

The component applied to the foil, in particular the copper foil, to be press-bonded may in particular be a conducting wire, especially a copper wire, which, after press-bonding, is arranged in the interior of the circuit board element and is contacted from outside via etched pads (so-called wire-inscribed circuit boards).

Said component may, however, also be configured as a plate-like shaped part, in particular as a shaped part consisting of copper, extending in the circuit board element. By means of such a shaped part, for example, the conductor cross-sections required for keeping under control the currents and the heat quantities occurring in the field of power electronics can be provided with little effort.

### BRIEF DESCRIPTION OF THE DRAWINGS

In the following, the present invention will now be explained in more detail making reference to two figures, the individual figures showing:

FIG. 1a a schematic cross-sectional view of the layers of a multilayer circuit board element according to the present invention, as imposed one on top of the other in the non-press-bonded state, and

FIG. 1b shows a schematic cross-sectional view of a multilayer circuit board element according to the present invention in a press-bonded state.

### DETAILED DESCRIPTION

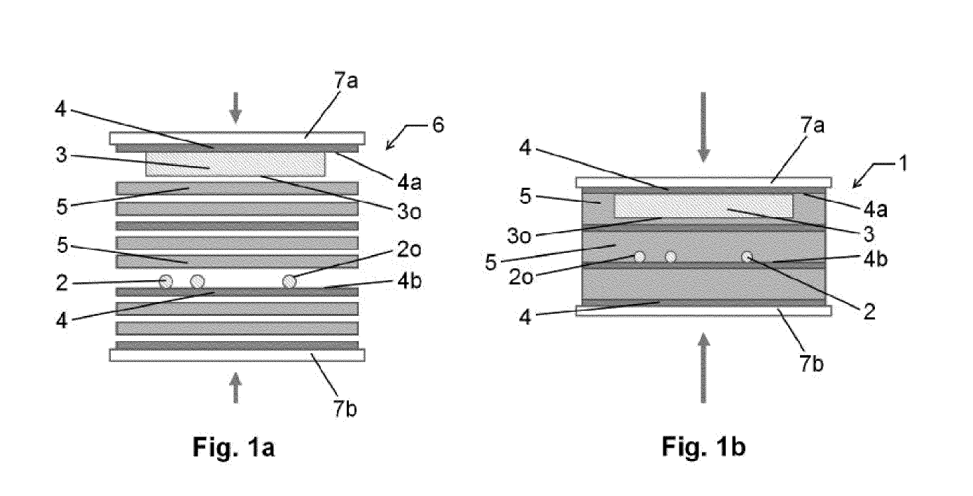

In FIGS. 1a and 1b, the individual material layers of a circuit board element 1 according to the present invention are shown, each in a cross-sectional view, with different area fillings for better discrimination. Components 2, 3, which are embedded in the circuit board element 1, are each obliquely hatched. The copper foils 4 are shown in a dark full tone, whereas the layers of epoxy resin glass fiber fabric 5, referred to generally as prepreg in the following, are shown in a pale full tone, in a cross-sectional view.

The components consisting of three circular cylindrical copper wires 2 on the one hand and of a plate-like shaped part 3 made of copper, e.g. in the form of a flat copper wire, on the other, have been fixed, in a preceding method step, to the respective sides 4a, 4b of a copper foil 4. This method step of fixing the components 2, 3 to the copper foils 4, which is not shown in the figures, is carried out by means of a numerically controlled device for establishing an integral connection, which has already been described in WO 2006/077167 A2, said connection being preferably established at defined contact points by means of resistance spot welding. The wires 2 are here actively caused to follow, held down at a defined target position, cut and welded by means of a welding electrode which is also displaceable in a controllable manner.

A shaped part 3 in the sense of the present invention is preferably a component that is produced in a separation process, in which the shape of a workpiece is changed, the shaped part 3 being separated from the workpiece and the final shape being comprised in the initial shape. In FIGS. 1a and 1b, the upper copper foil 4 is provided with a plate-like shaped part 3, which has been separated from a copper plate, on the lower surface 4a thereof. The copper foil 4 and the shaped part 3 have been contacted with one another, again at precisely defined connection points, by a process for establishing an integral connection, such as resistance spot welding.

FIG. 1a shows the cross-sectional view of an intermediate product of the method for producing the multilayer circuit board element 1 according to the present invention. This intermediate product shows the structure of a layer stack 6 comprising a plurality of superimposed electrically insulating layers of prepreg 5 and a plurality of conductive layers of copper foil 4, said layers being shown in a vertically spaced relationship with one another only for the purpose of better illustration. Two of the copper foils 4 have been populated with additional components (wires 2 and shaped part 3, respectively) on one side 4a, 4b thereof according to the above described method step, these two copper foils 4 being oriented in the layer stack 6 such that the foil side 4a, 4b contacting the component 2, 3 faces the interior of the layer stack 6, so that, after press-bonding, the components 2, 3 will always be located in the interior of the circuit board element 1.

According to FIG. 1a, the above described layer stack 6 is introduced between the press plates 7a, 7b of a laminate press, and subsequently a pressure (cf. the arrows pointing towards one another in FIGS. 1a and 1b) is applied, according to FIG. 1b, by means of the press plates 7a, 7b to the layers of the circuit board element 1 to be laminated and, simultaneously, the temperature of the layers to be laminated is increased to a desired temperature above room temperature.

Reference should be made to the fact that the pressing process illustrated through the transition from FIG. 1a to FIG. 1b has been shown in a highly simplified mode, since the production of a multilayer circuit board element 1 is executed, in practice, by means of a multi-step process. According to this process, first the middle layers of the layer stack 6 with layers of prepreg 5 positioned between a lower and an upper copper foil 4 are press-bonded so as to form an intermediate product. Subsequently, the outer copper foils 4 of this intermediate product are first etched from outside in the manner known. The etched copper foils 4 have applied thereto additional layers of prepreg 5 and final copper foils 4. Finally, this stack, which is not shown and which consists of an intermediate product that has already been press-bonded and of additional outer layers, is press-bonded so as to form the finished multilayer circuit board element 1.

The respective prepreg 5 introduced between the copper foils 4 consists of an epoxy resin-impregnated glass fiber fabric as an insulating material compound, which is plasticized under the above described influence of pressure and heat and which, during subsequent curing, causes adhesion to the adjoining copper foils 4. The plate-like shaped part 3 attached to the lower surface 4a of the upper copper foil 4 becomes, during press-bonding, embedded in the insulating material compound of the prepreg 5 such that all sides of the shaped part 3 are, in full area, covered with the insulating material compound of the prepreg 5. Only the at least one contact point provided between the shaped part 3 and the copper foil 4 is not enclosed by the prepreg 5. The circular cylindrical conducting wires 2 also become embedded almost along the entire periphery thereof in the insulating material compound of the prepreg 5 during press-bonding. Also in this case, only the at least one contact point between the respective wire 2 and the copper foil 4 is not covered by the prepreg 5.

For accomplishing better adhesion between the prepreg 5 and the copper foil 4, it is known to pretreat the surfaces of the copper foils 4 by an oxidation process (“brown oxide” and “black oxides, respectively), so that during the subsequent press-bonding according to FIG. 1b, which is executed for forming the multilayer circuit board element 1, a better adhesive bond between the copper foils 4 and the insulating cover layers 5 (prepregs) can be ensured. However, in the case of the circuit board element 1 having the structure according to the present invention, special demands have to be satisfied with respect to delamination resistance, since the additional components 2, 3 embedded in the insulating material compound of the prepreg 5 lead to a weakening of the adhesive bond of the circuit board element 1. In contrast to the copper foil surfaces, the component surfaces 2o, 3o present only a very weak adhesion to the respective adjoining prepreg 5.

One of the reasons for this is that in wire-inscribed circuit boards (i.e. circuit boards whose copper foils 4 are welded to wires 2) silver-plated copper wires are normally used as embedded components. The outer silver layer of these wires has very good welding properties for accomplishing a reliable connection with the copper foil 4, but, due to the rather smooth surface of the silver layer, adhesion of the silver layer on the surrounding prepreg 5 is insufficient. This may result in local lift-offs of the silver layer of the component from the surrounding prepreg 5, which, in extreme cases, may become the origin of complete delamination and, consequently, of total failure of the circuit board element 1.

This is where the present invention comes in and eliminates the problem of poor adhesion between the embedded component 2, 3 and the surrounding layer of prepreg 5 by roughening, at least partially, the surface 2o, 3o of the component 2, 3, which contacts the prepreg 5. “Roughening” means here that, prior to the application of the cover layer 5 to the copper foil 4 and the resultant embedding of the component 2, 3 in said cover layer 5, the surface 2o, 3o of the component 2, 3 has been subjected to a specific roughening treatment so as to provide said surface 2o, 3o with a defined microroughness. Since this microroughness does not substantially affect the quality of the welded joint between the components 2, 3 and the copper foils 4, the components 2, 3 may already be pretreated in their semi-finished state as wire or plate ware with a high throughput rate and with little effort, before they are fed to the actual circuit board production process.

The roughening treatment may consist of chemical roughening, where the component surface 2o, 3o is brought into contact with an etching solution in a multistep immersion and/or spraying process and the surface material is thus partially etched away, or it may consist of mechanical roughening, where the component surface 2o, 3o has mechanical forces applied thereto.

It will be advantageous to carry out chemical roughening in multi-stage plants comprising a plurality of modules in series, the surfaces 2o, 3o of the components passed continuously through the plant being in most cases cleaned, rinsed and pre-immersed prior to the actual microetching process and rinsed once more after the microetching process so as to remove the etching solution residues. Mechanical roughening may e.g. be executed by using a dense mass of minute balls consisting of e.g. steel, glass, pumice powder, quartz powder or the like, or by means of brush roughening techniques. Likewise, it would be imaginable to accomplish the roughening by incorporating a simple profile (e.g. notches) in the component surface 2o, 3o.

Due to the roughened surface 2o, 3o of the component 2, 3, the layer of the prepreg 5 contacting the component 2, 3 will have, after press-bonding and curing, a corresponding roughness that is complementary to the roughness of the component surface 2o, 3o. The fact that the interengaging roughness peaks of the component surface 2o, 3o and of the adjoining layer of the prepreg 5 become entangled with one another accounts for the excellent adhesion between the component 2, 3 and the prepreg 5.

Through the improvement according to the present invention, components 2, 3 can easily be integrated in the interior layers of circuit board elements 1 without any risk of delamination or crack formation and, consequently, operational failures of the circuit board element 1. This applies especially also to high-temperature applications, such as automotive electronics or solar technology, where the connection between the surface 2o, 3o of the embedded component 2, 3 and the surrounding prepreg 5 is subjected to constantly recurring strong loads due to the different coefficients of thermal expansion of the two materials.

Hence, the present invention contributes to a further increase in the integration density of components 2, 3 in circuit board elements 1 on the one hand, and, on the other hand, it widens the application spectrum of such circuit board elements 1 such that even high-temperature applications are comprised.

1. A method of producing a circuit board element comprising the following steps:
providing a component comprising an electrically conductive material,
contacting the component with an electrically conductive foil at at least one contact point,
applying a cover layer to the side of the foil contacting the component,
wherein a surface of the component is at least partially roughened prior to applying the cover layer, and that the cover layer is brought into contact with the roughened surface of the component.

2. The method according to claim 1, wherein roughening of a surface of the component takes place prior to contacting the component with the foil.

3. The method according to claim 1 wherein the surface of the component is roughened by chemical etching, said chemical etching being preferably executed by immersing the component into a liquid etching the material of the component or by spraying such a liquid onto the component.

4. The method according to claim 1 wherein the surface of the component is roughened by mechanical processing.

5. The method according to one of the claim 1, wherein contacting of the component with the foil is executed by welding.

6. The method according to one of the claim 1 wherein the application of a cover layer to the side of the foil contacting the component is executed by press-bonding the side of the foil with a prepreg made of an insulating material compound.

7. The method according to claim 6, wherein the applying the cover layer step further comprise the step of press-bonding a plurality of electrically conductive foils, at least one of which has been contacted with at least one component made of an electrically conductive material, and a plurality of prepregs made of an insulating material compound and inserted between the respective foils together so as to form a multilayer circuit board element.

8. A circuit board element, comprising:
at least one electrically conductive foil,
at least one cover layer, which covers the foil on at least one side thereof,
at least one component made of an electrically conductive material, the component being in contact with the foil at at least one contact point and being embedded in the cover layer, at least in certain areas thereof, preferably in full area,
wherein at least a part of a surface of the component that contacts the cover layer is roughened.

9. The circuit board element according to claim 8, wherein the component is configured as a conducting wire, which is preferably made of copper and which is circular or rectangular in cross-section.

10. The circuit board element according to claim 8, wherein the component is configured as a plate-like shaped part.

11. The circuit board element according to claim 10, wherein the component is preferably made of copper

12. The method according to claim 1, wherein the mechanical processing, is at least one of sand blasting and by spraying on at least one of pumice or quartz powder under high pressure.

13. The method according to claim 5, wherein the welding is resistance welding.
